(19) United States
(12) Patent Application Publication
(10) Pub. No.: US 2023/0369330 A1
(43) Pub. Date: Nov. 16, 2023

(54) SEMICONDUCTOR DEVICE AND METHOD FOR FABRICATING THE SAME

(71) Applicant: Samsung Electronics Co., Ltd., Suwon-is (KR)

(72) Inventors: Sun Ki MIN, Suwon-is (KR); Sang Hyun PARK, Suwon-is (KR)

(73) Assignee: Samsung Electronics Co., Ltd., Suwon-is (KR)

(21) Appl. No.: 18/165,563

(22) Filed: Feb. 7, 2023

(30) Foreign Application Priority Data
May 10, 2022 (KR) 10-2022-0057007

(51) Int. Cl. H01L 27/092; H01L 29/06; H01L 29/423; H01L 29/775; H01L 29/66; H01L 21/8238

(52) U.S. Cl. CPC H01L 27/092; H01L 29/0673; H01L 29/42392; H01L 29/775; H01L 29/66439; H01L 21/823878

(57) ABSTRACT

A semiconductor device includes a first active pattern extending in a first direction on a substrate, and a second active pattern extending in the first direction on the substrate, the second active pattern spaced apart from the first active pattern in a second direction. The device includes a field insulating film between the first active pattern and the second active pattern on the substrate, a first gate electrode intersecting the first active pattern on the substrate, a second gate electrode intersecting the second active pattern on the substrate, and a gate separation structure on the field insulating film. The gate separation structure separates the first gate electrode and the second gate electrode from each other, the gate separation structure includes a plurality of first sub-insulating films and at least one second sub-insulating film, and the at least one second sub-insulating film is between the first sub-insulating films.

### CROSS-REFERENCE TO RELATED APPLICATION

This application claims priority from Korean Patent Application No. 10-2022-0057007 filed on May 10, 2022, in the Korean Intellectual Property Office, and all the benefits accruing therefrom under 35 U.S.C. 119, the contents of which in its entirety are herein incorporated by reference.

### FIELD

Some example embodiments of the inventive concepts relate to a semiconductor device and/or a method for fabricating the same.

### BACKGROUND

As one of the scaling techniques for increasing a density of semiconductor devices, a multi-gate transistor in which a multi-channel active pattern (or silicon body) having a fin or nanowire shape is formed on a substrate and a gate is formed on a surface of the multi-channel active pattern has been proposed.

Since such a multi-gate transistor uses a three-dimensional channel, it is easy to perform scaling. In addition, the multi-gate transistor may improve current control capability even without increasing a gate length of the multi-gate transistor. In addition, the multi-gate transistor may effectively suppress a short channel effect (SCE) in which a potential of a channel region is affected by a drain voltage.

### SUMMARY

Some example embodiments of the inventive concepts provide a semiconductor device capable of having improved reliability.

Some example embodiments of the inventive concepts provide a method for fabricating a semiconductor device capable of fabricating a semiconductor device having improved reliability.

According to some example embodiments of the inventive concepts, a semiconductor device includes a first active pattern extending in a first direction on a substrate, a second active pattern extending in the first direction on the substrate, the second active pattern spaced apart from the first active pattern in a second direction, a field insulating film between the first active pattern and the second active pattern on the substrate, a first gate electrode intersecting the first active pattern on the substrate, a second gate electrode intersecting the second active pattern on the substrate, and a gate separation structure on the field insulating film, the gate separation structure separating the first gate electrode and the second gate electrode from each other, the gate separation structure including a plurality of first sub-insulating films and at least one second sub-insulating film, and the at least one second sub-insulating film between the first sub-insulating films.

According to some example embodiments of the inventive concepts, a semiconductor device includes a first active pattern extending in a first direction on a substrate, a second active pattern extending in the first direction on the substrate, the second active pattern spaced apart from the first active pattern in a second direction, a field insulating film between the first active pattern and the second active pattern on the substrate, a first gate electrode intersecting the first active pattern on the substrate, a second gate electrode intersecting the second active pattern on the substrate, and a gate insulating film between the field insulating film and the first gate electrode, the gate insulating film between the field insulating film and the second gate electrode, the gate insulating film between the first gate electrode and the first active pattern, and the gate insulating film between the second gate electrode and the second active pattern. The device includes a first gate separation structure on the field insulting film, the first gate separation structure separating the first gate electrode and the second gate electrode from each other, wherein the gate insulating film does not extend along a sidewall of the first gate separation structure, the first gate separation structure includes a plurality of insulating films including silicon nitride, the first gate separation structure includes a plurality of oxide films between the plurality of insulating films, and the plurality of insulating films and the plurality of oxide films are alternately stacked and have a convex shape toward the field insulating film.

According to some example embodiments of the inventive concepts, a semiconductor device includes a first active pattern extending in a first direction on a substrate, the first active pattern including a first lower pattern in a PMOS region, and the first active pattern including a first sheet pattern spaced apart from the first lower pattern, and a second active pattern extending in the first direction, the second active pattern spaced apart from the first active pattern in a second direction, the second active pattern including a second lower pattern in an NMOS region, and the second active pattern including a second sheet pattern spaced apart from the second lower pattern. The device includes a field insulating film between the first lower pattern and the second lower pattern on the substrate, a first gate electrode intersecting the first active pattern on the substrate, a second gate electrode intersecting the second active pattern on the substrate, and a gate separation structure on the field insulating film, the gate separation structure separating the first gate electrode and the second gate electrode from each other, the gate separation structure including a plurality of insulating films, and the gate separation structure including a plurality of oxide films between the plurality of insulating films. The gate separation structure includes a first sidewall facing the first active pattern, and a second sidewall facing the second active pattern, and at a same height in a third direction perpendicular to the first direction and the second direction, a first distance between the first sidewall and the first active pattern is smaller than a second distance between the second sidewall and the second active pattern.

According to some example embodiments of the inventive concepts, a method for fabricating a semiconductor device includes forming a field insulating film on a substrate, and forming a first active pattern and a second active pattern, the first active pattern and the second active pattern extending in a first direction, and the first active pattern and the second active pattern spaced apart from each other in a second direction with the field insulating film between the first active pattern and the second active pattern. The method includes forming a pre-gate electrode extending in the second direction on the first active pattern and the second active pattern, the pre-gate electrode intersecting the first active pattern and the second active pattern, forming a trench penetrating through the pre-gate electrode between the first active pattern and the second active pattern, the trench exposing the field insulating film, forming a first insulating film extending along a lower surface of the trench, the first insulation film not extending along an inner side surface of the trench in the trench, and forming a second insulating film extending along the first insulating film, the second insulating film not extending along the inner side surface of the trench on the first insulating film.

However, example embodiments of the inventive concepts are not restricted to those set forth herein. The above and other example embodiments of the inventive concepts will become more apparent by referencing the detailed description of some example embodiments given below.

### BRIEF DESCRIPTION OF THE DRAWINGS

The above and other features of the inventive concepts will become more apparent by describing in detail example embodiments thereof with reference to the attached drawings, in which:

FIG. 1 is a layout view for describing a semiconductor device according to some example embodiments.

FIGS. 2 and 3 are cross-sectional views taken along line A-A of FIG. 1.

FIG. 4 is a cross-sectional view taken along line B-B of FIG. 1.

FIG. 5 is an enlarged view of portion R of FIG. 4.

FIG. 6 is a cross-sectional view taken along line C-C of FIG. 1.

FIGS. 7, 8 and 9 are views for describing a semiconductor device according to some other example embodiments.

FIGS. 10 and 11 are views for describing a semiconductor device according to some other example embodiments.

FIG. 12 is a layout view for describing a semiconductor device according to some example embodiments.

FIG. 13 is a cross-sectional view taken along line B-B of FIG. 12.

FIGS. 14, 15, 16,17, 18, 19, 20, 21, 22, 23, 24 and 25 are intermediate step views for describing a method for fabricating a semiconductor device according to some example embodiments.

### DETAILED DESCRIPTION

In the drawings related to a semiconductor device according to some example embodiments, for example, a fin-type transistor (FinFET) including a channel region having a fin-shaped pattern shape and a transistor including a nanowire or a nanosheet are illustrated, but the inventive concepts are not limited thereto. For example, some technical ideas of the inventive concepts may be applied to two-dimensional (2D) material based FETs and a heterostructure thereof.

In addition, the semiconductor device according to some example embodiments may include a tunneling FET or a three-dimensional (3D) transistor. The semiconductor device according to some example embodiments may also include a bipolar junction transistor, a lateral double-diffused metal oxide semiconductor (LDMOS) transistor, or the like.

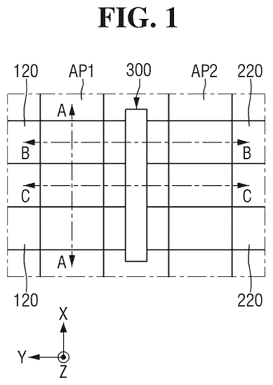

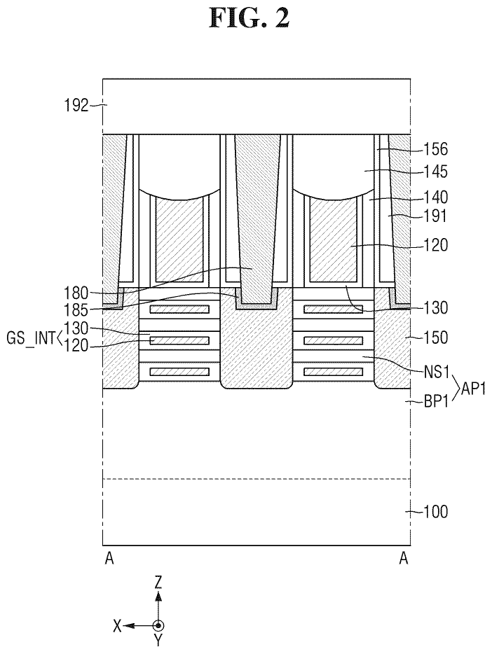

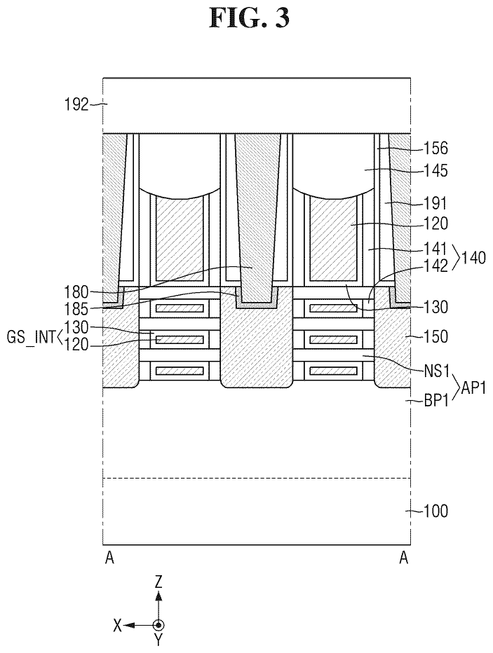

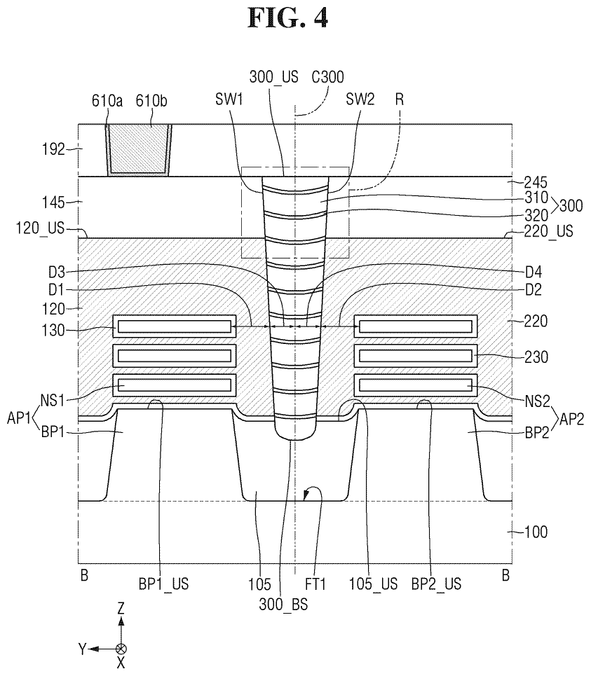

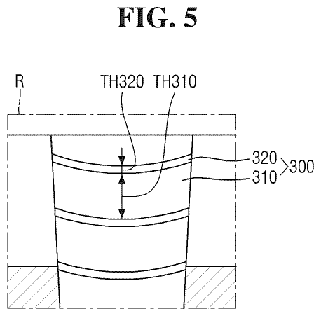

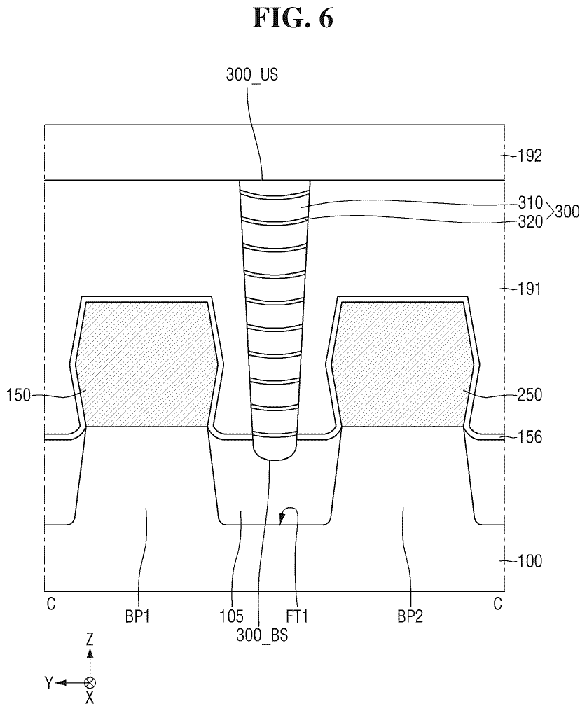

FIG. 1 is a layout view for describing a semiconductor device according to some example embodiments. FIGS. 2 and 3 are cross-sectional views taken along line A-A of FIG. 1. FIG. 4 is a cross-sectional view taken along line B-B of FIG. 1. FIG. 5 is an enlarged view of portion R of FIG. 4. FIG. 6 is a cross-sectional view taken along line C-C of FIG. 1.

Referring to FIGS. 1 to 6, a semiconductor device according to some example embodiments may include a first active pattern AP1, a second active pattern AP2, a first gate electrode 120, a second gate electrode 220, and a gate separation structure 300.

The first active pattern AP1 and the second active pattern AP2 may be disposed on a substrate 100. Each of the first active pattern AP1 and the second active pattern AP2 may extend in a first direction X to be long. The first active pattern AP1 and the second active pattern AP2 may be adjacent to each other in a second direction Y. The first active pattern AP1 and the second active pattern AP2 may be disposed to be spaced apart from each other in the second direction Y. For example, the first direction X is a direction intersecting the second direction Y.

The first active pattern AP1 and the second active pattern AP2 may be included in a channel region of a transistor of the same conductive type. Specifically, the first active pattern AP1 and the second active pattern AP2 may be regions in which an NMOS is formed.

The first active pattern AP1 may include a first lower pattern BP1 and a plurality of first sheet patterns NS1. The second active pattern AP2 may include a second lower pattern BP2 and a plurality of second sheet patterns NS2.

Each of the first lower pattern BP1 and the second lower pattern BP2 may protrude from the substrate 100. Each of the first lower pattern BP1 and the second lower pattern BP2 may extend in the first direction X to be long. Each of the first lower pattern BP1 and the second lower pattern BP2 may have a fin-shaped pattern shape.

The first lower pattern BP1 may be spaced apart from the second lower pattern BP2 in the second direction Y. The first lower pattern BP1 and the second lower pattern BP2 may be separated by a first fin trench FT1 extending in the first direction X.

The plurality of first sheet patterns NS1 may be disposed on the first lower pattern BP1. The plurality of first sheet patterns NS1 may be spaced apart from the first lower pattern BP1 in a third direction Z. The plurality of second sheet patterns NS2 may be disposed on the second lower pattern BP2. The plurality of second sheet patterns NS2 may be spaced apart from the second lower pattern BP2 in the third direction Z.

The respective first sheet patterns NS1 may be sequentially disposed in the third direction Z. The respective first sheet patterns NS1 may be spaced apart from each other in the third direction Z. The respective second sheet patterns NS2 may be sequentially disposed in the third direction Z. The respective second sheet patterns NS2 may be spaced apart from each other in the third direction Z.

Although it is illustrated that three first sheet patterns NS1 and three second sheet patterns NS2 are disposed in the third direction Z, respectively, this is only for convenience of explanation, and the inventive concepts are not limited thereto. For example, four first sheet patterns NS1 and four second sheet patterns NS2 are disposed in the third direction Z, respectively.

Each of the first lower pattern BP1 and the second lower pattern BP2 may be formed by etching a portion of the substrate 100, and may include an epitaxial layer grown from the substrate 100. Each of the first lower pattern BP1 and the second lower pattern BP2 may include silicon or germanium, which is an elemental semiconductor material. In addition, each of the first lower pattern BP1 and the second lower pattern BP2 may include a compound semiconductor, for example, a group IV-IV compound semiconductor or a group III-V compound semiconductor, but example embodiments are not limited thereto.

The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element, but example embodiments are not limited thereto.

The III-V compound semiconductor may be, for example, one of a binary compound, a ternary compound, or a quaternary compound formed by combining at least one of aluminum (Al), gallium (Ga), and indium (In) as a group III element and one of phosphorus (P), arsenic (As), and antimonium (Sb), which are group V elements, but example embodiments are not limited thereto.

Each of the first sheet pattern NS1 and the second sheet pattern NS2 may include one of silicon or germanium, which is an elemental semiconductor material, a group IV-IV compound semiconductor, or a group III-V compound semiconductor, but example embodiments are not limited thereto. A width of the first sheet pattern NS1 in the second direction Y may increase or decrease in proportion to a width of the first lower pattern BP1 in the second direction Y. A description of the second sheet pattern NS2 may be the same as that of the first sheet pattern NS1.

A first field insulating film 105 may be formed on the substrate 100. The first field insulating film 105 may fill at least a portion of the first fin trench FT1.

The first field insulating film 105 may be disposed on the substrate 100 between the first active pattern AP1 and the second active pattern AP2. An additional active pattern used as a channel region of the transistor may not be interposed between the first active pattern AP1 and the second active pattern AP2. The first field insulating film 105 may be disposed between the first lower pattern BP1 and the second lower pattern BP2. The first field insulating film 105 may be in contact with the first lower pattern BP1 and the second lower pattern BP2.

As an example, the first field insulating film 105 may entirely cover a sidewall of the first lower pattern BP1 and a sidewall of the second lower pattern BP2 defining the first fin trench FT1. Unlike as illustrated, as another example, the first field insulating film 105 may cover a portion the sidewall of the first lower pattern BP1 and/or a portion of the sidewall of the second lower pattern BP2 defining the first fin trench FT1. For example, a portion of the first lower pattern BP1 and/or a portion of the second lower pattern BP2 may protrude in the third direction Z from an upper surface 105_US of the first field insulating film. The first field insulating film 105 does not cover an upper surface BP1_US of the first lower pattern and an upper surface BP2_US of the second lower pattern. Each of the first sheet patterns NS1 and each of the second sheet patterns NS2 is disposed to be higher than the upper surface 105_US of the first field insulating film.

The first field insulating film 105 may include, for example, an oxide film, a nitride film, an oxynitride film, or a combination thereof, but example embodiments are not limited thereto. Although it is illustrated that the first field insulating film 105 is a single film, the inventive concepts are not limited thereto. Unlike as illustrated, the first field insulating film 105 may also include a field liner extending along a sidewall and a bottom surface of the first fin trench FT1 and a field filling film on the field liner.

Each of the first gate electrode 120 and the second gate electrode 220 may be disposed on the substrate 100. The first gate electrode 120 may be disposed on the first active pattern AP1. The first gate electrode 120 may extend in the second direction Y to intersect the first active pattern AP1. The first gate electrode 120 may intersect the first lower pattern BP1. The first gate electrode 120 may surround each of the first sheet patterns NS1.

The second gate electrode 220 may be disposed on the second active pattern AP2. The second gate electrode 220 may extend in the second direction Y to intersect the second active pattern AP2. The second gate electrode 220 may intersect the second lower pattern BP2. The second gate electrode 220 may surround each of the second sheet patterns NS2. The second gate electrode 220 may be spaced apart from the first gate electrode 120 in the second direction Y. The second gate electrode 220 may be separated from the first gate electrode 120.

Each of the first gate electrode 120 and the second gate electrode 220 may include at least one of a metal, a metal alloy, conductive metal nitride, metal silicide, a doped semiconductor material, conductive metal oxide, and conductive metal oxynitride, but example embodiments are not limited thereto. Each of the first gate electrode 120 and the second gate electrode 220 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt)), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but example embodiments are not limited thereto. The conductive metal oxide and the conductive metal oxynitride may include oxidized forms of the above-described materials, but example embodiments are not limited thereto.

The gate electrode 120 may be disposed on both sides of a first source/drain pattern 150, which will be described later. As an example, all of the first gate electrodes 120 disposed on both sides of the first source/drain pattern 150 may be normal gate electrodes used as gates of the transistor. As another example, the gate electrode 120 disposed on one side of the first source/drain pattern 150 is used as the gate of the transistor, but the gate electrode 120 disposed on the other side of the first source/drain pattern 150 may be a dummy gate electrode. The description of the first gate electrode 120 described above may also correspond to the second gate electrode 220.

A first gate insulating film 130 may extend along the upper surface 105_US of the first field insulating film and the upper surface BP1_US of the first lower pattern. The first gate insulating film 130 may surround each of the first sheet patterns NS1. The first gate insulating film 130 may be disposed along a circumference of each of the first sheet patterns NS1.

A second gate insulating film 230 may extend along the upper surface 105_US of the first field insulating film and the upper surface BP2_US of the second lower pattern. The second gate insulating film 230 may surround each of the second sheet patterns NS2. The second gate insulating film 230 may be disposed along a circumference of each of the second sheet patterns NS2.

The first gate electrode 120 and the second gate electrode 220 may be disposed on the first gate insulating film 130 and the second gate insulating film 230, respectively. The first gate insulating film 130 and the second gate insulating film 230 may be disposed between the first gate electrode 120 and the second gate electrode 220 and the first active pattern AP1 and the second active pattern AP2.

Each of the first gate insulating film 130 and the second gate insulating film 230 may include silicon oxide, silicon oxynitride, silicon nitride, or a high-k material having a dielectric constant greater than that of silicon oxide. The high-k material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but example embodiments are not limited thereto.

Although it is illustrated that each of the first gate insulating film 130 and the second gate insulating film 230 is a single film, this is only for convenience of explanation, and the inventive concepts are not limited thereto. Each of the first gate insulating film 130 and the second gate insulating film 230 may include a plurality of films. As an example, the first gate insulating film 130 may include an interfacial layer disposed between the first sheet pattern NS1 and the first gate electrode 120 and a high dielectric constant insulating film.

The semiconductor device according to some example embodiments may include a negative capacitance (NC) FET using a negative capacitor. For example, each of the first gate insulating film 130 and the second gate insulating film 230 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected to each other in series and the capacitance of each capacitor has a positive value, a total capacitance decreases as compared with a capacitance of each individual capacitor. On the other hand, when at least one of the capacitances of two or more capacitors connected to each other in series has a negative value, the total capacitance may be greater than an absolute value of each individual capacitance while having a positive value.

When the ferroelectric material film having the negative capacitance and the paraelectric material film having the positive capacitance are connected to each other in series, a total capacitance value of the ferroelectric material film and the paraelectric material film connected to each other in series may increase. A transistor including the ferroelectric material layer may have a subthreshold swing (SS) less than 60 mV/decade at room temperature by using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O), but example embodiments are not limited thereto.

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn), but example embodiments are not limited thereto. A type of dopant included in the ferroelectric material film may vary depending on a type of ferroelectric material included in the ferroelectric material film.

When the ferroelectric material film includes hafnium oxide, the dopant included in the ferroelectric material layer may include, for example, at least one of gadolinium (Gd), silicon (Si), zirconium (Zr), aluminum (Al), and yttrium (Y), but example embodiments are not limited thereto.

When the dopant is aluminum (Al), the ferroelectric material film may include a range of 3 to 8 atomic % (at %) of aluminum. Here, a ratio of the dopant may be a ratio of aluminum to the sum of hafnium and aluminum.

When the dopant is silicon (Si), the ferroelectric material film may include a range of 2 to 10 at % of silicon. When the dopant is yttrium (Y), the ferroelectric material film may include a range of 2 to 10 at % of yttrium. When the dopant is gadolinium (Gd), the ferroelectric material film may contain a range of 1 to 7 at % of gadolinium. When the dopant is zirconium (Zr), the ferroelectric material film may include a range of 50 to 80 at % of zirconium.

The paraelectric material film may have the paraelectric characteristics. The paraelectric material film may include, for example, at least one of silicon oxide and metal oxide having a high dielectric constant. The metal oxide included in the paraelectric material film may include, for example, at least one of hafnium oxide, zirconium oxide, and aluminum oxide, but example embodiments are not limited thereto.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include the hafnium oxide, a crystal structure of the hafnium oxide included in the ferroelectric material film is different from a crystal structure of the hafnium oxide included in the paraelectric material film.

The ferroelectric material film may have a thickness having the ferroelectric characteristics. The thickness of the ferroelectric material film may be, for example, in a range of 0.5 to 10 nm, but example embodiments are not limited thereto. Since a critical thickness representing the ferroelectric characteristics may vary for each ferroelectric material, the thickness of the ferroelectric material film may vary depending on the ferroelectric material.

As an example, each of the first gate insulating film 130 and the second gate insulating film 230 may include one ferroelectric material film. As another example, each of the first gate insulating film 130 and the second gate insulating film 230 may include a plurality of ferroelectric material films spaced apart from each other. Each of the first gate insulating film 130 and the second gate insulating film 230 may have a stacked film structure in which a plurality of ferroelectric material films and a plurality of paraelectric material films are alternately stacked.

An inter-gate structure GS_INT may be disposed between the first sheet patterns NS1 adjacent in the third direction Z and between the first lower pattern BP1 and the first sheet pattern NS1. The inter-gate structure GS_INT may include the first gate electrode 120 and the first gate insulating film 130 disposed between the first sheet patterns NS1 adjacent to each other and between the first lower pattern BP1 and the first sheet pattern NS1. Although not illustrated, the inter-gate structure GS_INT may be disposed between the second sheet patterns NS2 adjacent in the third direction Z and between the second lower pattern BP2 and the second sheet pattern NS2.

A gate spacer 140 may be disposed on a sidewall of the first gate electrode 120. The gate spacer 140 may extend in the second direction Y.

In FIG. 2, the gate spacer 140 is not disposed between the first sheet patterns NS1 adjacent in the third direction Z and between the first sheet pattern NS1 and the first lower pattern BP1. The gate spacer 140 may include only an outer spacer.

In FIG. 3, the gate spacer 140 may be disposed between the first sheet patterns NS1 adjacent in the third direction Z and between the first sheet pattern NS1 and the first lower pattern BP1. The gate spacer 140 may include an outer spacer 141 and an inner spacer 142. The inner spacer 142 may be disposed between the first sheet patterns NS1 adjacent in the third direction Z and between the first sheet pattern NS1 and the first lower pattern BP1. The inner spacer 142 may be in contact with the first gate insulating film 130 of the inter-gate structure GS_INT.

The gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof, but example embodiments are not limited thereto.

FIGS. 2 and 3 are views cut along the first active pattern AP1. Although not illustrated, a view cut along the second active pattern AP2 may be substantially the same as that of FIG. 2 or 3.

A first gate capping pattern 145 may be disposed on an upper surface 120_US of the first gate electrode. A second gate capping pattern 245 may be disposed on an upper surface 220_US of the second gate electrode.

The first gate capping pattern 145 illustrated in FIGS. 2 and 3 will be described as an example. The first gate capping pattern 145 may be disposed on an upper surface of the gate spacer 140. Unlike illustrated, the first gate capping pattern 145 may be disposed between the gate spacers 140.

Each of the first gate capping pattern 145 and the second gate capping pattern 245 may include, for example, at least one of silicon nitride (SiN), silicon oxynitride (SiON), silicon oxide (SiO₂), silicon carbonitride (SiCN), silicon oxycarbonitride (SiOCN), and a combination thereof, but example embodiments are not limited thereto.

A first source/drain pattern 150 may be formed on the first active pattern AP1. The first source/drain pattern 150 may be disposed on the first lower pattern BP1. A second source/drain pattern 250 may be formed on the second active pattern AP2. The second source/drain pattern 250 may be disposed on the second lower pattern BP2.

The first source/drain pattern 150 illustrated in FIGS. 2 and 3 will be described as an example. The first source/drain pattern 150 may be disposed on a side surface of the first gate electrode 120. The first source/drain pattern 150 may be disposed between the first gate electrodes 120. The first source/drain pattern 150 may be disposed on at least one side of the first gate electrode 120. For example, the first source/drain pattern 150 may be disposed on both sides of the first gate electrode 120. Unlike illustrated, the first source/drain pattern 150 may be disposed on one side of the first gate electrode 120 and may not be disposed on the other side of the first gate electrode 120.

Each of the first source/drain pattern 150 and the second source/drain pattern 250 may include an epitaxial pattern. Each of the first source/drain pattern 150 and the second source/drain pattern 250 may include, for example, a semiconductor material.

The first source/drain pattern 150 may be included in a source/drain of a transistor using the first active pattern AP1, for example, the first sheet pattern NS1 as a channel region. The second source/drain pattern 250 may be included in a source/drain of a transistor using the second sheet pattern NS2 as a channel region.

A source/drain etching stop film 156 may be disposed along the upper surface 105_US of the first field insulating film and a profile of the first source/drain pattern 150.

The source/drain etching stop film 156 may include a material having an etching selectivity with respect to a first interlayer insulating film 191, which will be described later. The source/drain etching stop film 156 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and a combination thereof, but example embodiments are not limited thereto. Unlike illustrated, the source/drain etching stop film 156 may not be formed.

A first interlayer insulating film 191 may be formed on the first field insulating film 105. The first interlayer insulating film 191 may be disposed on the first source/drain pattern 150 and the second source/drain pattern 250. For example, the first interlayer insulating film 191 does not cover an upper surface of the first gate capping pattern 145.

A second interlayer insulating film 192 may be disposed on the first interlayer insulating film 191. The second interlayer insulating film 192 may be disposed on the first gate capping pattern 145 and the second gate capping pattern 245.

The first interlayer insulating film 191 and the second interlayer insulating film 192 may include, for example, at least one of silicon oxide, silicon nitride, silicon oxynitride, and a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane

(HMDS), trimethylsilyl borate (TMSB), diacetoxyditertiarybutosiloxane (DADBS), trimethylsilyl phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but example embodiments are not limited thereto.

A source/drain contact 180 is connected to the first source/drain pattern 150. The source/drain contact 180 may pass through the first interlayer insulating film 191 and the source/drain etching stop film 156 to be connected to the first source/drain pattern 150.

A metal silicide film 185 may be further disposed between the source/drain contact 180 and the first source/drain pattern 150.

A first wiring pattern may be disposed in the second interlayer insulating film 192. The first wiring pattern may include a portion in direct contact with the first gate capping pattern 145. The first wiring pattern may have a multi-conductive film structure. The first wiring pattern may include, for example, a first wiring barrier film 610a and a first wiring filling film 610b. The first wiring filling film 610b may be disposed on the first wiring barrier film 610a. The first wiring barrier film 610a may be disposed along a sidewall and a bottom surface of the first wiring filling film 610b.

The first wiring barrier film 610a may include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material, but example embodiments are not limited thereto.

The first wiring filling film 610b may each include, for example, at least one of aluminum (Al), copper (Cu), tungsten (W), cobalt (Co), ruthenium (Ru), silver (Ag), gold (Au), manganese (Mn), and molybdenum (Mo), but example embodiments are not limited thereto.

The gate separation structure 300 may be disposed on the first field insulating film 105. The gate separation structure 300 may be disposed between the first active pattern AP1 and the second active pattern AP2. The gate separation structure 300 may separate the first gate electrode 120 and the second gate electrode 220 from each other. The gate separation structure 300 may separate the first gate capping pattern 145 and the second gate capping pattern 245 from each other.

The gate separation structure 300 may extend from the first field insulating film 105 to an upper surface of the first interlayer insulating film 191. In FIG. 6, the gate separation structure 300 passing between the first source/drain pattern 150 and the second source/drain pattern 250 may be disposed in the first interlayer insulating film 191.

The gate separation structure 300 may include a first sidewall SW1 facing the first active pattern AP1 and a second sidewall SW2 facing the second active pattern AP2. The first sidewall SW1 may be in contact with the first gate capping pattern 145. The second sidewall SW2 may be in contact with the second gate capping pattern 245.

The gate separation structure 300 may be in direct contact with the first gate electrode 120 and the second gate electrode 220. Specifically, the first sidewall SW1 may be in contact with the first gate electrode 120. The second sidewall SW2 may be in contact with the second gate electrode 220.

The gate separation structure 300 may include a plurality of first sub-insulating films 310 and a plurality of second sub-insulating films 320. The plurality of first sub-insulating films 310 and the plurality of second sub-insulating films 320 may be alternately stacked. The plurality of first sub-insulating films 310 may be disposed between the plurality of second sub-insulating films 320. The plurality of second sub-insulating films 320 may be disposed between the plurality of first sub-insulating films 310.

The plurality of first sub-insulating films 310 and the plurality of second sub-insulating films 320 may have a curved shape. Specifically, the plurality of first sub-insulating films 310 and the plurality of second sub-insulating films 320 may have a shape convex toward the first field insulating film 105.

The plurality of first sub-insulating films 310 may have a thickness greater than that of the plurality of second sub-insulating films 320. Specifically, the plurality of first sub-insulating films 310 may have a first thickness TH_310 in the third direction Z. The plurality of second sub-insulating films 320 may have a second thickness TH_320 in the third direction Z. In some example embodiments, the first thickness TH_310 may be greater than the second thickness TH_320.

The gate separation structure 300 may have a symmetrical or substantially symmetrical structure between the first active pattern AP1 and the second active pattern AP2. Specifically, the gate separation structure 300 may be symmetrical or substantially symmetrical with respect to a central axis C300 of the uppermost surface 300_US of the gate separation structure 300 in the second direction Y.

At the same height in the third direction Z, a first distance D1 between the first sidewall SW1 and the first active pattern AP1 in the second direction Y may be the same or substantially the same as a second distance D2 between the second sidewall SW2 and the second active pattern AP2. Specifically, the first distance D1 between the first sidewall SW1 of the gate separation structure 300 and the first sheet pattern NS1 may be the same or substantially the same as the second distance D2 between the second sidewall SW2 of the gate separation structure 300 and the second sheet pattern NS2.

A third distance D3 of the uppermost surface 300_US of the gate separation structure 300 in the second direction Y from the central axis C300 to the first sidewall SW1 may be the same or substantially the same as a fourth distance D4 of the uppermost surface 300_US of the gate separation structure 300 in the second direction Y from the central axis C300 to the second sidewall SW2.

The lowermost surface 300_BS of the gate separation structure 300 may be disposed below the upper surface 105_US of the first field insulating film 105. The lowermost surface 300_BS of the gate separation structure 300 may be disposed between the first lower pattern BP1 and the second lower pattern BP2. The lowermost surface 300_BS of the gate separation structure 300 may be disposed at the center between the first active pattern AP1 and the second active pattern AP2. The lowermost surface 300_BS of the gate separation structure 300 may be disposed at the center of the first field insulating film 105 in the second direction Y.

Although it is illustrated in FIG. 4 that first sidewall SW1 and the second sidewall SW2 of the gate separation structure 300 do not have a convex shape but have a flat shape, the example embodiments are not limited thereto. For example, the first sidewall SW1 and the second sidewall SW2 of the gate separation structure 300 may have a shape convex toward the first active pattern AP1 and the second active pattern AP2, respectively.

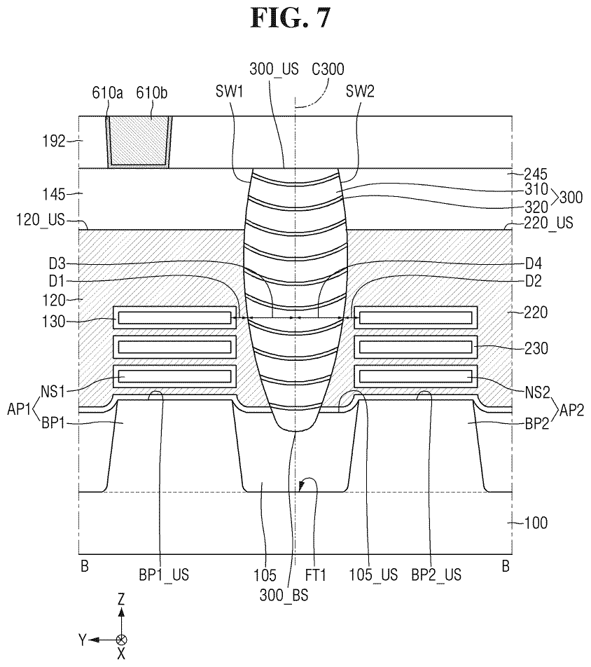

FIGS. 7 to 9 are views for describing a semiconductor device according to some other example embodiments.

Referring to FIG. 7, the first active pattern AP1 and the second active pattern AP2 may be included in a channel region of a transistor of the same conductive type. Specifically, the first active pattern AP1 and the second active pattern AP2 may be regions in which a PMOS is formed.

The gate separation structure 300 may have a symmetrical or substantially symmetrical structure between the first active pattern AP1 and the second active pattern AP2. Specifically, the gate separation structure 300 may be symmetrical or substantially symmetrical with respect to a central axis C300 of the uppermost surface 300_US of the gate separation structure 300 in the second direction Y.

At the same height in the third direction Z, a first distance D1 between the first sidewall SW1 and the first active pattern AP1 in the second direction Y may be the same or substantially the same as a second distance D2 between the second sidewall SW2 and the second active pattern AP2. Specifically, the first distance D1 between the first sidewall SW1 of the gate separation structure 300 and the first sheet pattern NS1 may be the same or substantially the same as the second distance D2 between the second sidewall SW2 of the gate separation structure 300 and the second sheet pattern NS2.

A third distance D3 of the uppermost surface 300_US of the gate separation structure 300 in the second direction Y from the central axis C300 to the first sidewall SW1 may be the same or substantially the same as a fourth distance D4 of the uppermost surface 300_US of the gate separation structure 300 in the second direction Y from the central axis C300 to the second sidewall SW2.

In FIG. 7, the first sidewall SW1 and the second sidewall SW2 of the gate separation structure 300 may have a more curved shape compared to that of FIG. 4. Specifically, when the first active pattern AP1 is the channel of the transistor in the region in which the PMOS is formed, compared to when the first active pattern AP1 is the channel of the transistor in the region in which the NMOS is formed, the first sidewall SW1 of the gate separation structure 300 may have a shape more convexly curved toward the first active pattern AP1.

When the second active pattern AP2 is the channel of the transistor in the region in which the PMOS is formed, compared to when the second active pattern AP2 is the channel of the transistor in the region in which the NMOS is formed, the second sidewall SW2 of the gate separation structure 300 may have a shape more convexly curved toward the second active pattern AP2.

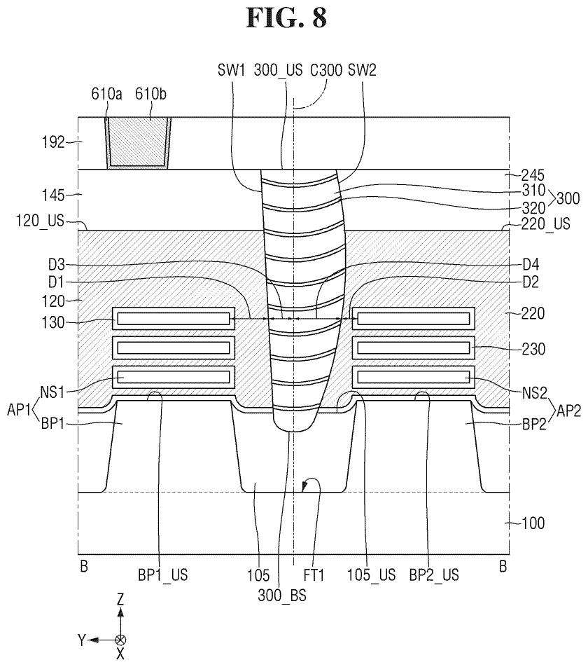

Referring to FIG. 8, the first active pattern AP1 and the second active pattern AP2 may be included in channel regions of transistors of different conductive types. Specifically, the first active pattern AP1 may be a region in which an NMOS is formed. The second active pattern AP2 may be a region in which a PMOS is formed.

The gate separation structure 300 may have an asymmetric structure between the first active pattern AP1 and the second active pattern AP2. Specifically, the gate separation structure 300 may be asymmetric with respect to a central axis C300 of the uppermost surface 300_US of the gate separation structure 300 in the second direction Y.

At the same height in the third direction Z, a first distance D1 between the first sidewall SW1 and the first active pattern AP1 in the second direction Y may be different from a second distance D2 between the second sidewall SW2 and the second active pattern AP2. Specifically, the first distance D1 between the first sidewall SW1 of the gate separation structure 300 and the first sheet pattern NS1 may be greater than the second distance D2 between the second sidewall SW2 of the gate separation structure 300 and the second sheet pattern NS2.

A third distance D3 of the uppermost surface 300_US of the gate separation structure 300 in the second direction Y from the central axis C300 to the first sidewall SW1 may be different from a fourth distance D4 of the uppermost surface 300_US of the gate separation structure 300 in the second direction Y from the central axis C300 to the second sidewall SW2. Specifically, the third distance D3 may be smaller than the fourth distance D4.

The degree to which the second sidewall SW2 of the gate separation structure 300 is curved toward the second active pattern AP2 may be greater than the degree to which the first sidewall SW1 of the gate separation structure 300 is curved toward the first active pattern AP1. The second sidewall SW2 of the gate separation structure 300 may have a more convex shape toward the second active pattern AP2 than the first sidewall SW1. That is, a curvature of the second sidewall SW2 may be greater than a curvature of the first sidewall SW1.

Even in this case, the lowermost surface 300_BS of the gate separation structure 300 may be disposed at the center between the first active pattern AP1 and the second active pattern AP2. The lowermost surface 300_BS of the gate separation structure 300 may be disposed at the center of the first field insulating film 105 in the second direction Y.

Although it is illustrated in FIG. 8 that first sidewall SW1 of the gate separation structure 300 does not have a convex shape but has a flat sidewall, the example embodiments are not limited thereto. For example, the first sidewall SW1 of the gate separation structure 300 may have a shape convex toward the first active pattern AP1 like second sidewall SW2. However, in some example embodiments, the degree to which the first sidewall SW1 is curved toward the first active pattern AP1 is smaller than the degree to which the second sidewall SW2 is curved toward the second active pattern AP2.

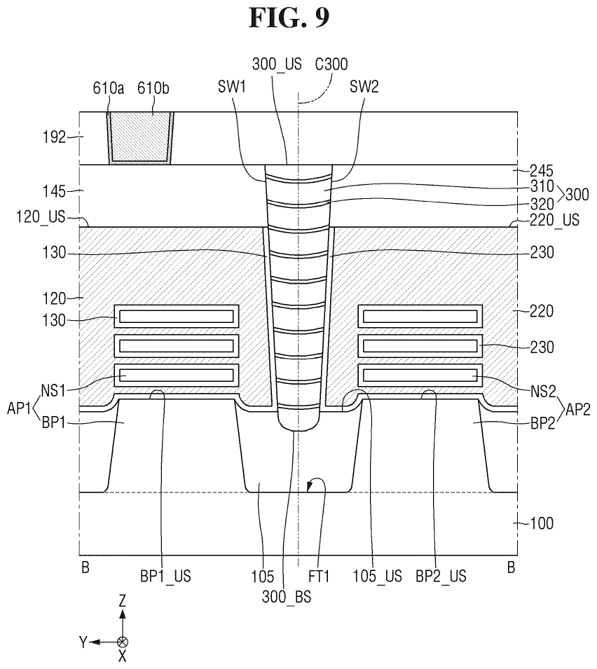

Referring to FIG. 9, the gate separation structure 300 may not be in direct contact with the first gate electrode 120 and the second gate electrode 220. Specifically, the first gate insulating film 130 may be disposed between the gate separation structure 300 and the first gate electrode 120. The first gate insulating film 130 may extend along the first sidewall SW1 of the gate separation structure 300. The second gate insulating film 230 may be disposed between the gate separation structure 300 and the second gate electrode 220. The second gate insulating film 230 may extend along the second sidewall SW2 of the gate separation structure 300.

The first sidewall SW1 of the gate separation structure 300 may be in contact with the first gate insulating film 130. The second sidewall SW2 of the gate separation structure 300 may be in contact with the second gate insulating film 230.

Although it is illustrated in FIG. 9 that the gate separation structure 300 has the symmetrical structure with respect to the central axis C300 of the uppermost surface 300_US, the example embodiments are not limited thereto. For example, in some example embodiments in which the gate separation structure 300 has an asymmetric structure with respect to the central axis C300 of the uppermost surface 300_US, the first gate insulating film 130 and the second gate insulating film 230 may extend along the first sidewall SW1 and the second sidewall SW2 of the gate separation structure 300.

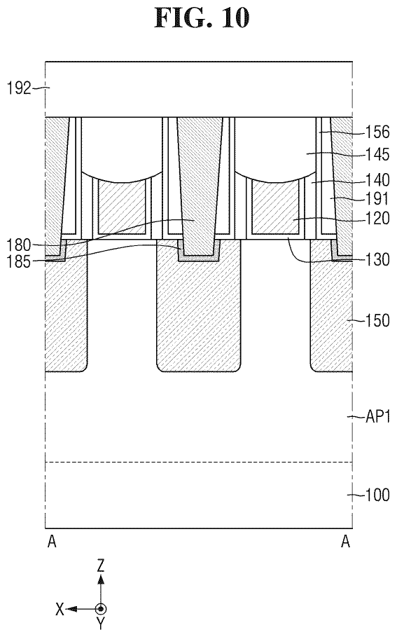

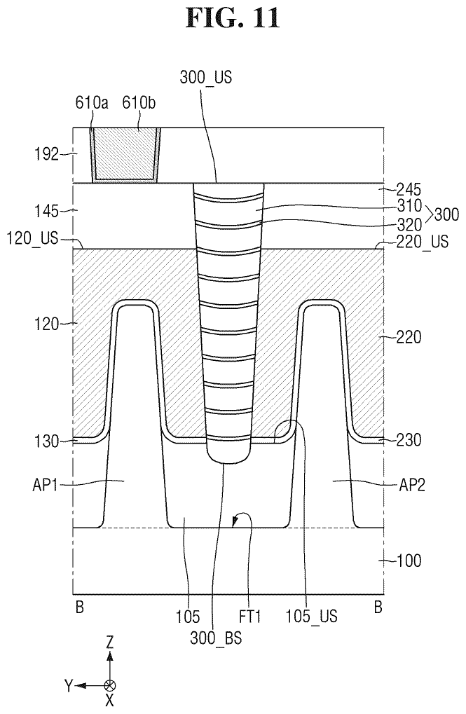

FIGS. 10 and 11 are views for describing a semiconductor device according to some other example embodiments. For convenience of explanation, points different from those described with reference to FIGS. 1 to 9 will be mainly described.

Referring to FIGS. 10 and 11, in a semiconductor device according to some example embodiments, each of the first active pattern AP1 and the second active pattern AP2 may be a fin-shaped pattern protruding upward compared to the upper surface 105_US of the first field insulating film.

The fin-shaped pattern protruding upward compared to the upper surface 105_US of the first field insulating film may be used as a channel region of the transistor.

Although not illustrated, as an example, a deep trench deeper than the first fin trench FT1 may be disposed between the first active pattern AP1 and the second active pattern AP2. As another example, a dummy fin pattern may be disposed between the first active pattern AP1 and the second active pattern AP2. A height of the dummy fin pattern is lower than a height of the first active pattern AP1 and a height of the second active pattern AP2. The first field insulating film 105 covers an upper surface of the dummy fin-shaped pattern.

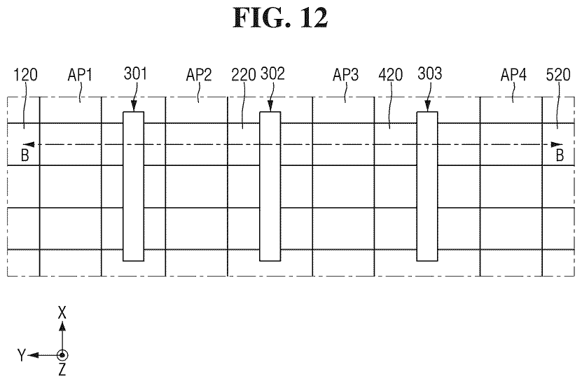

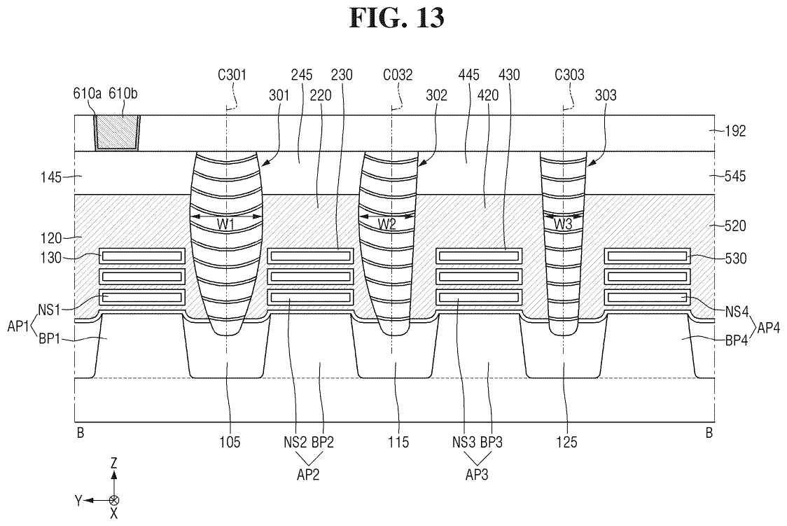

FIG. 12 is a layout view for describing a semiconductor device according to some example embodiments. FIG. 13 is a cross-sectional view taken along line B-B of FIG. 12. For convenience of explanation, points different from those described with reference to FIGS. 1 to 11 will be mainly described.

Referring to FIGS. 12 and 13, a semiconductor device according to some example embodiments may include a first active pattern AP1, a second active pattern AP2, a third active pattern AP3, and a fourth active pattern AP4. In addition, the semiconductor device according to some example embodiments may include a first gate electrode 120, a second gate electrode 220, a third gate electrode 420, and a fourth gate electrode 520. In addition, the semiconductor device according to some example embodiments may include first to third gate separation structures 301 to 303.

The third active pattern AP3 and the fourth active pattern AP4 may be disposed on a substrate 100. Each of the third active pattern AP3 and the fourth active pattern AP4 may extend in the first direction X to be long. The third active pattern AP3 and the fourth active pattern AP4 may be disposed to be spaced apart from each other in the second direction Y.

The first active pattern AP1 and the second active pattern AP2 may be included in a channel region of a transistor of the same conductive type. Specifically, the first active pattern AP1 and the second active pattern AP2 may be regions in which a PMOS is formed. The third active pattern AP3 and the fourth active pattern AP4 may be included in a channel region of a transistor of the same conductive type. Specifically, the third active pattern AP3 and the fourth active pattern AP4 may be regions in which an NMOS is formed. Accordingly, the second active pattern AP2 and the third active pattern AP3 may be included in channel regions of transistors of different conductive types.

The first to third gate separation structures 301 to 303 may be disposed to be spaced apart from each other in the second direction Y.

The first gate separation structure 301 may be disposed on the first field insulating film 105. The first gate separation structure 301 may be disposed between the first active pattern AP1 and the second active pattern AP2. The first gate separation structure 301 may separate the first gate electrode 120 and the second gate electrode 220 from each other. The first gate separation structure 301 may separate the first gate capping pattern 145 and the second gate capping pattern 245 from each other.

The second gate separation structure 302 may be disposed on the second field insulating film 115. The second gate separation structure 302 may be disposed between the second active pattern AP2 and the third active pattern AP3. The second gate separation structure 302 may separate the second gate electrode 220 and the third gate electrode 420 from each other. The second gate separation structure 302 may separate the second gate capping pattern 245 and a third gate capping pattern 345 from each other.

The third gate separation structure 303 may be disposed on a third field insulating film 125. The third gate separation structure 303 may be disposed between the third active pattern AP3 and the fourth active pattern AP4. The third gate separation structure 303 may separate the third gate electrode 420 and the fourth gate electrode 520 from each other. The third gate separation structure 303 may separate a third gate capping pattern 445 and a fourth gate capping pattern 545 from each other.

The first to third gate separation structures 301 to 303 may have different widths in the second direction Y at the same height in the third direction Z, respectively. At the same height in the third direction Z, the first gate separation structure 301 may have a first width W1. At the same height in the third direction Z, the second gate separation structure 302 may have a second width W2. At the same height in the third direction Z, the third gate separation structure 303 may have a third width W3. In some example embodiments, the first width W1 may be greater than the second width W2 and the third width W3. The second width W2 may be greater than the third width W3 and smaller than the first width W1. The third width W3 may be smaller than the first width W1 and the second width W2.

The first gate separation structure 301 and the third gate separation structure 303 may have a symmetrical or substantially symmetrical structure. The first gate separation structure 301 may have a symmetric or substantially symmetric structure in the second direction Y with respect to a first central axis C301. In this case, the first central axis C301 may refer to a line that vertically intersects the center of an upper surface of the first gate separation structure 301 in the second direction Y. The third gate separation structure 303 may have a symmetric or substantially symmetric structure in the second direction Y with respect to a third central axis C303. In this case, the third central axis C303 may refer to a line that vertically intersects the center of an upper surface of the third gate separation structure 303 in the second direction Y.

A sidewall of the first gate separation structure 301 may have a shape convex toward the first active pattern AP1 and the second active pattern AP2 compared to the third gate separation structure 303. On the other hand, a sidewall of the third gate separation structure 303 may have a shape that is not curved toward the first active pattern AP1 and the second active pattern AP2 compared to the first gate separation structure 301.

The second gate separation structure 302 may have an asymmetric structure unlike the first gate separation structure 301 and the third gate separation structure 303. The second gate separation structure 302 may have an asymmetric structure with respect to a second central axis C302 of the second gate separation structure 302. In this case, the second central axis C302 may refer to a line that vertically intersects the center of an upper surface of the second gate separation structure 302 in the second direction Y.

Specifically, a distance between one sidewall of the second gate separation structure 302 and the second active pattern AP2 may be greater than a distance between the other sidewall of the second gate separation structure 302 and the third active pattern AP3. The semiconductor device of FIG. 13 may include a fourth gate insulating film 430.

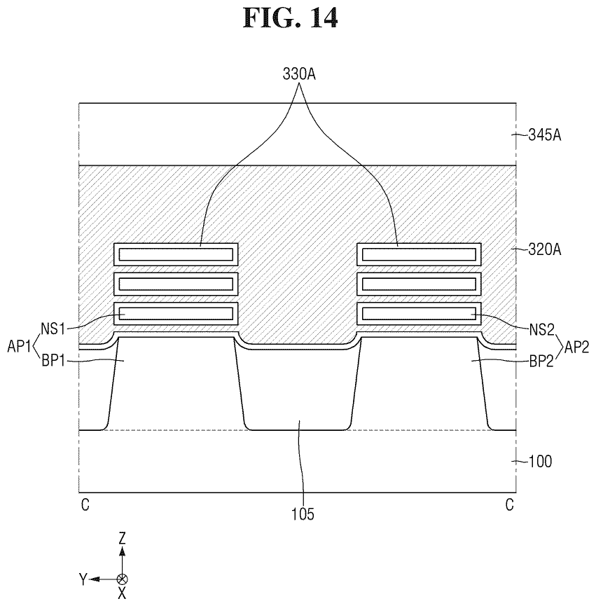

FIGS. 14 to 25 are intermediate step views for describing a method for fabricating a semiconductor device according to some example embodiments. For reference, FIGS. 14 to 25 are views for explaining a method for fabricating the semiconductor device of FIG. 7.

Referring to FIG. 14, a first pre-gate electrode 320A and a first pre-gate capping pattern 345A are formed on the first active pattern AP1, the second active pattern AP2, and the first field insulating film 105 extending in the first direction X.

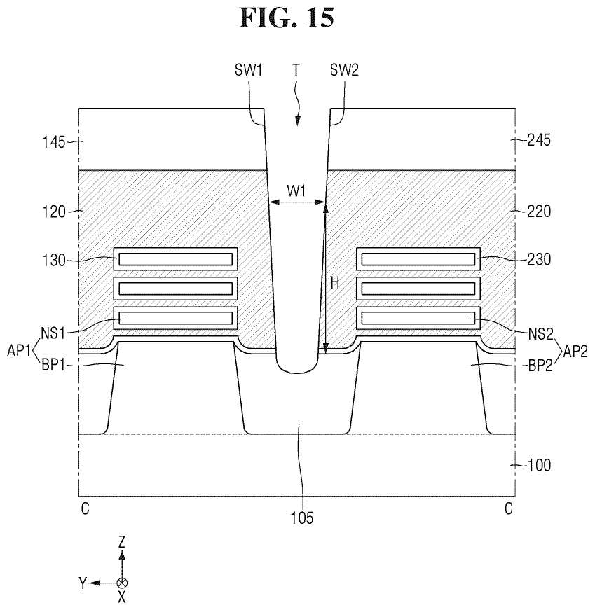

Referring to FIG. 15, a trench T penetrating through the first pre-gate electrode 320A and exposing the first field insulating film 105 is formed. In some example embodiments, the trench T may have a first width W1 in the second direction Y at a desired (or alternatively predetermined) height H in the third direction Z.

A first gate electrode 120 is formed on the first active pattern AP1 and a second gate electrode 220 is formed on the second active pattern AP2 by the trench T. A first gate capping pattern 145 is formed on the first gate electrode 120 and a second gate capping pattern 245 is formed on the second gate electrode 220 by the trench T. That is, the trench T may separate the first gate electrode 120 and the second gate electrode 220 from each other. The trench T may separate the first gate capping pattern 145 and the second gate capping pattern 245 from each other.

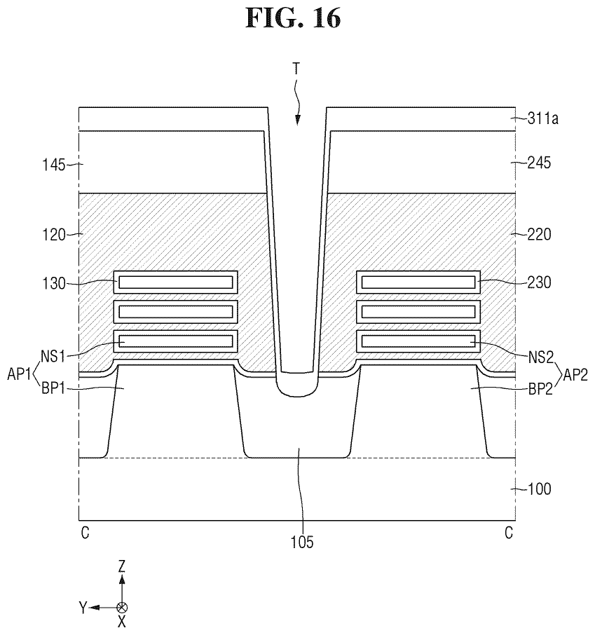

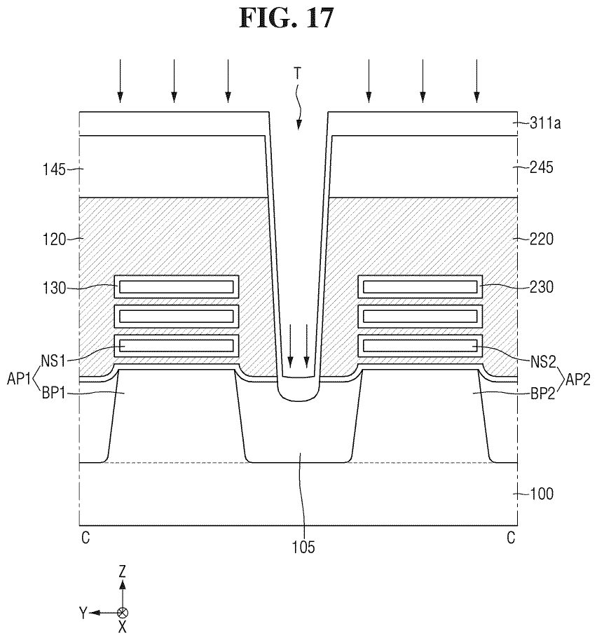

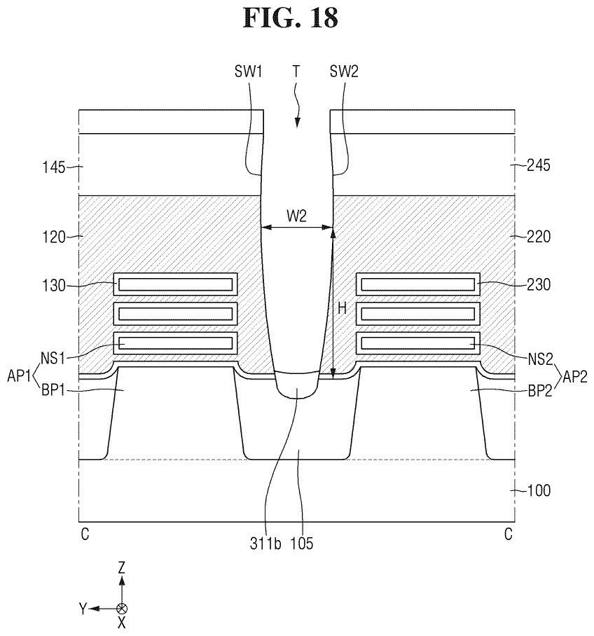

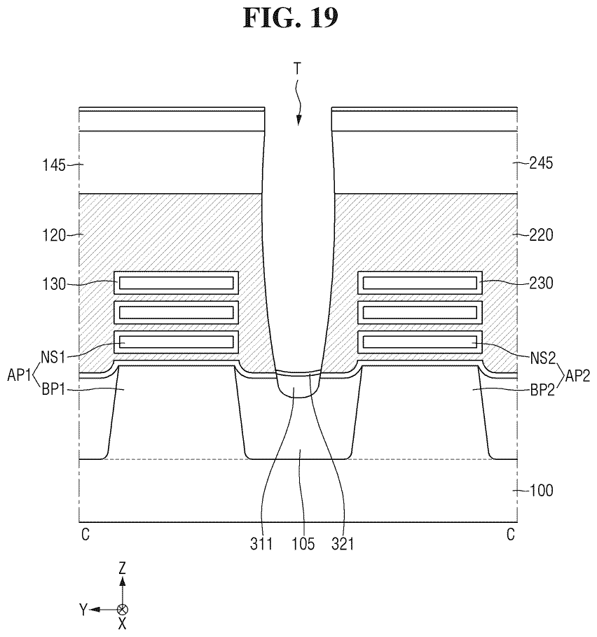

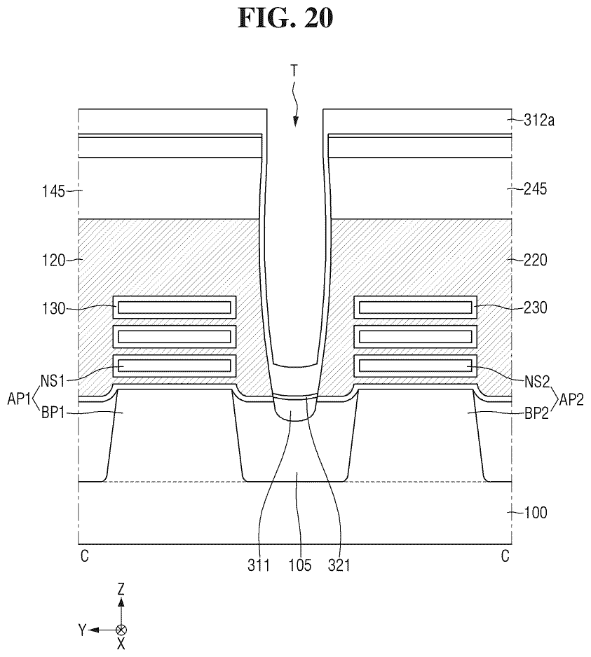

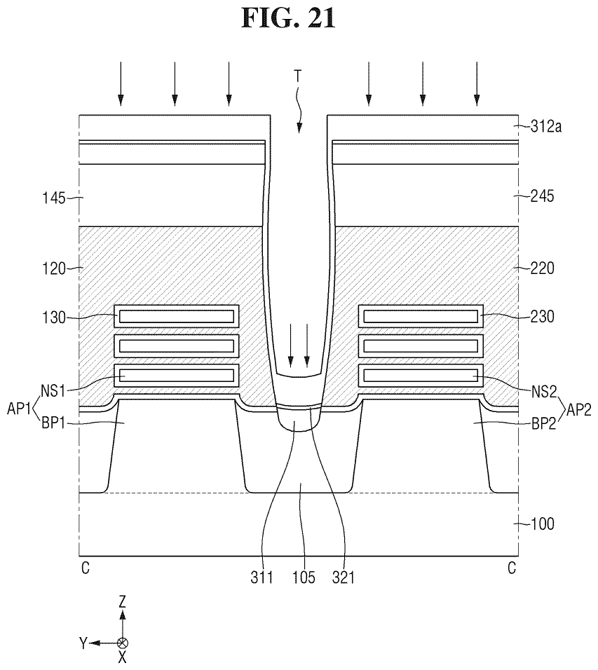

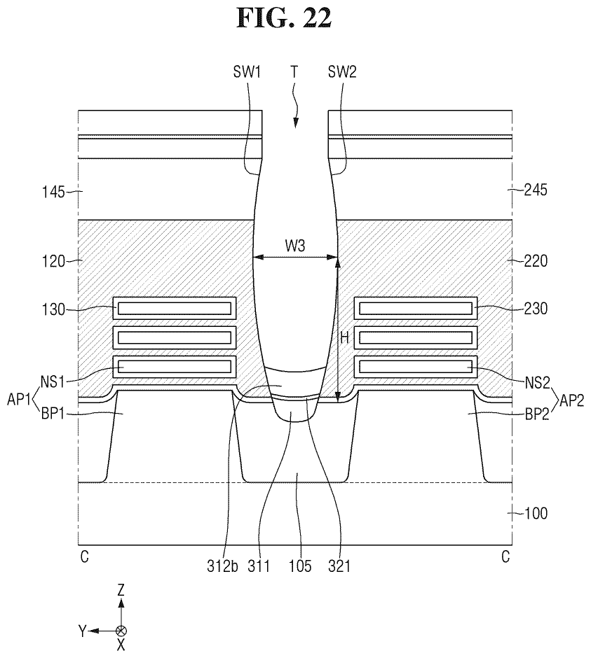

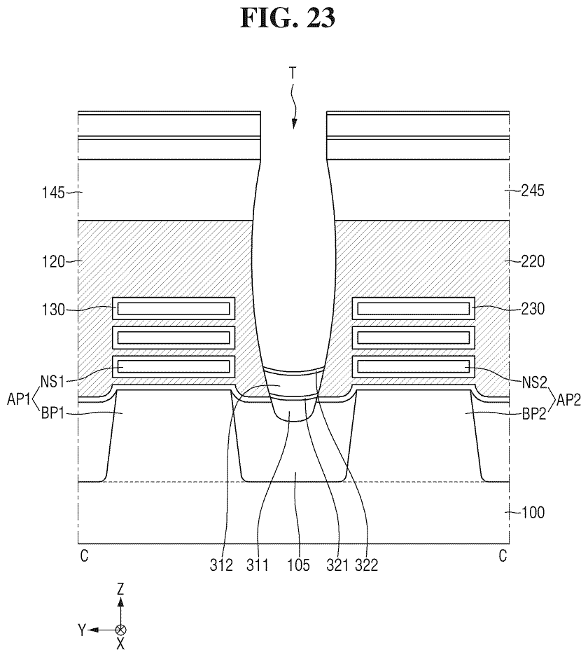

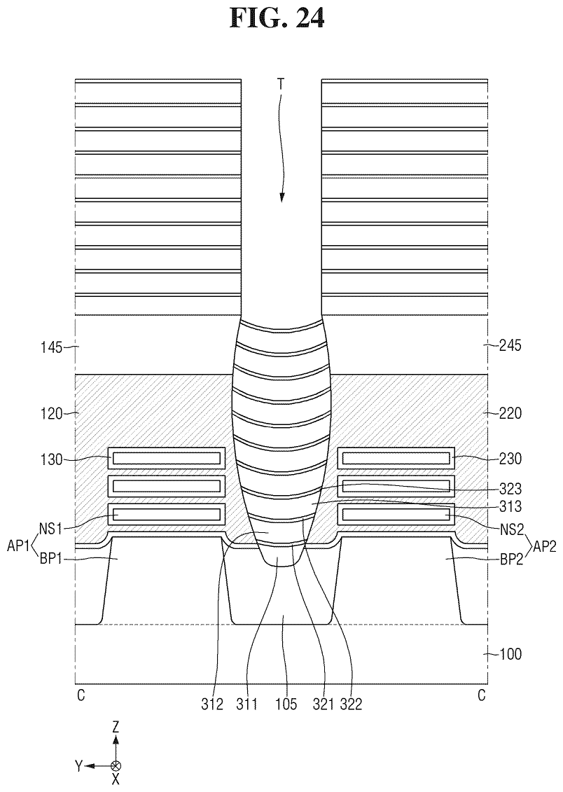

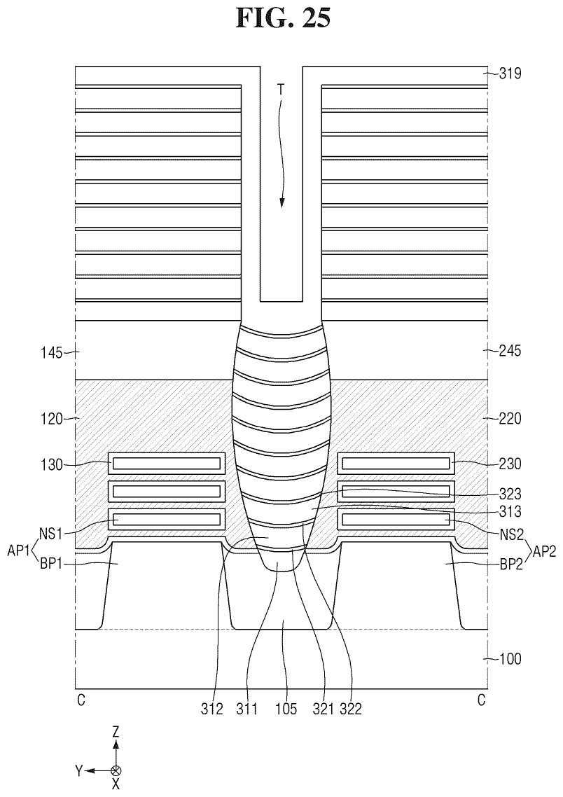

Referring to FIG. 16, a first pre-sub-insulating film 311a is formed in the trench T.

Specifically, the first pre-sub-insulating film 311a may be deposited along upper surfaces of the first gate capping pattern 145 and the second gate capping pattern 245 and a profile of the trench T. The first pre-sub-insulating film 311a may include silicon nitride.

Subsequently, referring to FIG. 17, a treatment process is performed on the first pre-sub-insulating film 311a.

Plasma treatment using hydrogen (H₂) and nitrogen (N₂) gases may be performed on the first pre-sub-insulating film 311a. Specifically, the plasma treatment may be performed on the first pre-sub-insulating film 311a formed on a lower surface of the trench T and the first pre-sub-insulating film 311a formed on the upper surfaces of the first gate capping pattern 145 and the second gate capping pattern 245.

A relatively small amount of plasma treatment may be performed on the first pre-sub-insulating film 311a formed along an inner sidewall of the trench T.

Referring to FIG. 18, the first pre-sub-insulating film 311a formed along the inner sidewall of the trench T is removed, and a second pre-sub-insulating film 311b is formed.

The second pre-sub-insulating film 311b may be formed on the lower surface of the trench T and the upper surfaces of the first gate capping pattern 145 and the second gate capping pattern 245. The second pre-sub-insulating film 311b does not extend along the inner sidewall of the trench T.

As the first pre-sub-insulating film 311a formed along the inner sidewall of the trench T is removed, the first pre-sub-insulating film 311a formed on the lower surface of the trench T may also be partially removed. Therefore, a thickness of the second pre-sub-insulating film 311b on the lower surface of the trench T may be smaller than that of the first pre-sub-insulating film 311a. As the first pre-sub-insulating film 311a formed on the inner sidewall of the trench T is removed, the second pre-sub-insulating film 311b may have an upper surface convex downward toward the first field insulating film 105.

After the first pre-sub-insulating film 311a formed on the inner sidewall of the trench T is removed, the trench T may have a second width W2 in the second direction Y at a desired (or alternatively predetermined) height H in the third direction Z. The second width W2 may be greater than the first width W1 of FIG. 15. That is, as the first pre-sub-insulating film 311a formed on the inner sidewall of the trench T is removed, the width of the trench T in the second direction Y may be expanded.

Referring to FIG. 19, a first unit sub-insulating film 311 and a second unit sub-insulating film 321 may be formed.

The second unit sub-insulating film 321 may be formed by oxidizing a surface of the second pre-sub-insulating film 311b. The first unit sub-insulating film 311 may include silicon nitride. The second unit sub-insulating film 321 may include an oxide film in which silicon nitride is oxidized.

Referring to FIG. 20, a third pre-sub-insulating film 312a is formed on the second unit sub-insulating film 321.

Specifically, the third pre-sub-insulating film 312a may be deposited on the inner sidewall of the trench T, an upper surface of the second unit sub-insulating film 321 in the trench T, and the second unit sub-insulating film 321 on the upper surfaces of the first gate capping pattern 145 and the second gate capping pattern 245. The third pre-sub-insulating film 312a may include silicon nitride.

Referring to FIG. 21, a treatment process is performed on the third pre-sub-insulating film 312a.

Plasma treatment using hydrogen (H₂) and nitrogen (N₂) gases may be performed on the third pre-sub-insulating film 312a. Specifically, the plasma treatment may be performed on the third pre-sub-insulating film 312a formed on the lower surface of the trench T and the third pre-sub-insulating film 312a formed on the upper surfaces of the first gate capping pattern 145 and the second gate capping pattern 245.

A relatively small amount of plasma treatment may be performed on the third pre-sub-insulating film 312a formed along the inner sidewall of the trench T.

Referring to FIG. 22, the third pre-sub-insulating film 312a formed along the inner sidewall of the trench T is removed, and a fourth pre-sub-insulating film 312b is formed.

The fourth pre-sub-insulating film 312b may be formed on the first unit sub-insulating film 311 and the second unit sub-insulating film 321 stacked on the lower surface of the trench T. The fourth pre-sub-insulating film 312b may be formed on the first unit sub-insulating film 311 and the second unit sub-insulating film 321 stacked on the upper surfaces of the first gate capping pattern 145 and the second gate capping pattern 245. That is, the fourth pre-sub-insulating film 312b does not extend along the inner sidewall of the trench T.

As the third pre-sub-insulating film 312a formed along the inner sidewall of the trench T is removed, the third pre-sub-insulating film 312a formed on the second unit sub-insulating film 321 in the trench T may also be partially removed. Therefore, a thickness of the fourth pre-sub-insulating film 312b on the lower surface of the trench T may be smaller than that of the third pre-sub-insulating film 312a. As the third pre-sub-insulating film 312a formed on the inner sidewall of the trench T is removed, the fourth pre-sub-insulating film 312b may have an upper surface convex downward toward the first field insulating film 105.

After the third pre-sub-insulating film 312a formed along the inner sidewall of the trench T is removed, the trench T may have a third width W3 in the second direction Y at a desired (or alternatively predetermined) height H in the third direction Z. The third width W3 may be greater than the second width W2 of FIG. 18. That is, as the third pre-sub-insulating film 312a formed on the inner sidewall of the trench T is removed, the width of the trench T in the second direction Y may be expanded.

Referring to FIG. 23, a third unit sub-insulating film 312 and a fourth unit sub-insulating film 322 may be formed.

The fourth unit sub-insulating film 322 may be formed by oxidizing a surface of the fourth pre-sub-insulating film 312b. The third unit sub-insulating film 312 may include silicon nitride. The fourth unit sub-insulating film 322 may include an oxide film in which silicon nitride is oxidized.

Referring to FIG. 24, by repeating the processes of FIGS. 15 to 23, a plurality of sub-insulating films including first to sixth unit sub-insulating films 311 to 313 and 321 to 323 may be formed.

A plurality of first sub-insulating films 310 including first, third, and fifth unit sub-insulating films 311, 312, and 313, and a plurality of second sub-insulating films 320 including second, fourth, and sixth unit sub-insulating films 321, 322, and 323 may be alternately formed. The plurality of first sub-insulating films 310 may include silicon nitride. The plurality of second sub-insulating films 320 may include an oxide film in which silicon nitride is oxidized.

Referring to FIG. 25, a unit sub-insulating film 319 may be additionally formed to completely fill the trench T.

The plurality of first sub-insulating films 310 and the plurality of second sub-insulating films 320 stacked on the first gate capping pattern 145 and the second gate capping pattern 245 may be removed after the plurality of first sub-insulating films 310 and the plurality of second sub-insulating films 320 are all formed in the trench T. For example, the plurality of first sub-insulating films 310 and the plurality of second sub-insulating films 320 stacked on the first gate capping pattern 145 and the second gate capping pattern 245 may be removed through a chemical mechanical polishing process.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

In concluding the detailed description, those skilled in the art will appreciate that many variations and modifications may be made to the example embodiments without substantially departing from the principles of the inventive concepts. Therefore, the disclosed example embodiments of the invention are used in a generic and descriptive sense only and not for purposes of limitation.

1. A semiconductor device comprising:
a first active pattern extending in a first direction on a substrate;
a second active pattern extending in the first direction on the substrate, the second active pattern spaced apart from the first active pattern in a second direction;
a field insulating film between the first active pattern and the second active pattern on the substrate;
a first gate electrode intersecting the first active pattern on the substrate;
a second gate electrode intersecting the second active pattern on the substrate; and
a gate separation structure on the field insulating film, the gate separation structure separating the first gate electrode and the second gate electrode from each other, the gate separation structure including a plurality of first sub-insulating films and at least one second sub-insulating film, and the at least one second sub-insulating film between the first sub-insulating films.

2. The semiconductor device of claim 1, wherein
a width of the gate separation structure increases as a distance from the field insulating film increases, and p1 after the width of the gate separation structure increases, the width of the gate separation structure then decreases as the distance from the field insulating film continues to increase.

3. The semiconductor device of claim 1, wherein
the first active pattern is included in a first channel region of a transistor,
the second active pattern is included in a second channel region of the transistor,
the first channel region and the second channel region have a same conductive type,
the gate separation structure includes a first sidewall facing the first active pattern and a second sidewall facing the second active pattern, and
a distance of an uppermost surface of the gate separation structure in the second direction from a central axis to the first sidewall, is same as a distance of the uppermost surface of the gate separation structure in the second direction from the central axis to the second sidewall.

4. The semiconductor device of claim 1, wherein
the gate separation structure includes a first sidewall facing the first active pattern and a second sidewall facing the second active pattern,
the first active pattern is in a PMOS region,
the second active pattern is in an NMOS region, and
at a same height in a third direction perpendicular to the first direction and the second direction, a distance of an uppermost surface of the gate separation structure in the second direction from a central axis to the first sidewall is greater than a distance of the uppermost surface of the gate separation structure in the second direction from the central axis to the second sidewall.

5. The semiconductor device of claim 1, further comprising a gate insulating film between the first gate electrode and the first active pattern, wherein
the gate insulating film is between the second gate electrode and the second active pattern, and
the gate insulating film does not extend along a sidewall of the gate separation structure.

6. The semiconductor device of claim 1, wherein
the plurality of first sub-insulating films includes a silicon nitride film, and
the second sub-insulating film includes an oxide.

7. The semiconductor device of claim 1, wherein in a third direction perpendicular to the first direction and the second direction, a thickness of the plurality of first sub-insulating films is greater than a thickness of the second sub-insulating film.

8. The semiconductor device of claim 1, wherein
the first active pattern includes a first lower pattern extending in the first direction, and a first sheet pattern spaced apart from the first lower pattern, and
the second active pattern includes a second lower pattern extending in the first direction, and a second sheet pattern spaced apart from the second lower pattern.

9. The semiconductor device of claim 1, wherein a lowest portion of the gate separation structure is at a center between the first active pattern and the second active pattern.

10. The semiconductor device of claim 1, wherein the plurality of first sub-insulating films are convexly curved toward the field insulating film.

11. The semiconductor device of claim 1, further comprising a gate insulating film between the first gate electrode and the first active pattern, wherein
the gate insulating film is between the second gate electrode and the second active pattern, and
the gate insulating film extends along a sidewall of the gate separation structure.

12. The semiconductor device of claim 1, wherein
the first active pattern is in a PMOS region,
the second active pattern is in an NMOS region, and
the gate separation structure has an asymmetric structure with respect to a central axis of an uppermost surface of the gate separation structure in the second direction.

13. The semiconductor device of claim 12, wherein
the gate separation structure includes a first sidewall facing the first active pattern, and a second sidewall facing the second active pattern, and
at a same height in a third direction perpendicular to the first direction and the second direction, a first distance between the first sidewall and the first active pattern is smaller than a second distance between the second sidewall and the second active pattern.

14. A semiconductor device comprising:
a first active pattern extending in a first direction on a substrate;
a second active pattern extending in the first direction on the substrate, the second active pattern spaced apart from the first active pattern in a second direction;
a field insulating film between the first active pattern and the second active pattern on the substrate;
a first gate electrode intersecting the first active pattern on the substrate;
a second gate electrode intersecting the second active pattern on the substrate;
a gate insulating film between the field insulating film and the first gate electrode, the gate insulating film between the field insulating film and the second gate electrode, the gate insulating film between the first gate electrode and the first active pattern, and the gate insulating film between the second gate electrode and the second active pattern; and
a first gate separation structure on the field insulting film, the first gate separation structure separating the first gate electrode and the second gate electrode from each other, wherein the gate insulating film does not extend along a sidewall of the first gate separation structure, the first gate separation structure includes a plurality of insulating films including silicon nitride, the first gate separation structure includes a plurality of oxide films between the plurality of insulating films, and the plurality of insulating films and the plurality of oxide films are alternately stacked and have a convex shape toward the field insulating film.

15. The semiconductor device of claim 14, wherein
the first active pattern is in a PMOS region,
the second active pattern is in an NMOS region, and
the first gate separation structure has an asymmetric structure with respect to a central axis of an uppermost surface of the first gate separation structure in the second direction.

16. The semiconductor device of claim 15, wherein
the first gate separation structure includes a first sidewall facing the first active pattern and a second sidewall facing the second active pattern, and
at a same height in a third direction perpendicular to the first direction and the second direction, a first distance between the first sidewall and the first active pattern is smaller than a second distance between the second sidewall and the second active pattern.

17. The semiconductor device of claim 14, further comprising:
a third active pattern extending in the first direction on the substrate, the third active pattern spaced apart from the second active pattern in the second direction;
a fourth active pattern extending in the first direction on the substrate, the fourth active pattern spaced apart from the third active pattern in the second direction;
a third gate electrode intersecting the third active pattern on the substrate;
a fourth gate electrode intersecting the fourth active pattern on the substrate;
a second gate separation structure separating the second gate electrode and the third gate electrode from each other, the second gate separation structure having a second width in the second direction; and
a third gate separation structure separating the third gate electrode and the fourth gate electrode from each other, the third gate separation structure having a third width in the second direction, wherein
the first gate separation structure has a first width in the second direction,
the first active pattern and the second active pattern are in a PMOS region,
the third active pattern and the fourth active pattern are in an NMOS region, and
at a same height in a third direction perpendicular to the first direction and the second direction, the second width is smaller than the first width and the second width is greater than the third width.

18. A semiconductor device comprising:
a first active pattern extending in a first direction on a substrate, the first active pattern including a first lower pattern in a PMOS region, and the first active pattern including a first sheet pattern spaced apart from the first lower pattern;
a second active pattern extending in the first direction, the second active pattern spaced apart from the first active pattern in a second direction, the second active pattern including a second lower pattern in an NMOS region, and the second active pattern including a second sheet pattern spaced apart from the second lower pattern;
a field insulating film between the first lower pattern and the second lower pattern on the substrate;
a first gate electrode intersecting the first active pattern on the substrate;
a second gate electrode intersecting the second active pattern on the substrate; and
a gate separation structure on the field insulating film, the gate separation structure separating the first gate electrode and the second gate electrode from each other, the gate separation structure including a plurality of insulating films, and the gate separation structure including a plurality of oxide films between the plurality of insulating films, wherein the gate separation structure includes a first sidewall facing the first active pattern, and a second sidewall facing the second active pattern, and
at a same height in a third direction perpendicular to the first direction and the second direction, a first distance between the first sidewall and the first active pattern is smaller than a second distance between the second sidewall and the second active pattern.

19. The semiconductor device of claim 18, wherein a lowest portion of the gate separation structure is at a center between the first active pattern and the second active pattern.

20. The semiconductor device of claim 18, further comprising a gate insulating film between the field insulating film and the first gate electrode, wherein
the gate insulating film is between the field insulating film and the second gate electrode,
the gate insulating film is between the first gate electrode and the first active pattern,
the gate insulating film is between the second gate electrode and the second active pattern, and
the gate insulating film does not extend along the first sidewall and the second sidewall of the gate separation structure.

21-25. (canceled)
